(19) United States
(12) Patent Application Publication
(10) Pub. No.: US 2018/0124873 A1
(43) Pub. Date: May 3, 2018

(54) HEATING ELEMENT

(71) Applicant: SHIN-ETSU CHEMICAL CO., LTD., Tokyo (JP)

(72) Inventor: Shoji KANO, Takasaki-shi (JP)

(73) Assignee: SHIN-ETSU CHEMICAL CO., LTD., Tokyo (JP)

(21) Appl. No.: 15/799,218

(22) Filed: Oct. 31, 2017

(30) Foreign Application Priority Data
Oct. 31, 2016 (JP) 2016-213030

(51) Int. Cl. H05B 3/14; H01L 21/67; H05B 3/44; H05B 3/74

(52) U.S. Cl. CPC H05B 3/143; H01L 21/67103; H01L 2021/6015; H05B 3/748; H05B 3/44

(57) ABSTRACT

A heating element in which, in a connecting portion of a rod portion in which the rod portion is connected to a heat generator, a connecting unit is provided in a face of the rod portion on which the rod portion is connected to the heat generator, a feeder terminal for feeding power to the heating element is formed on a face of the rod portion opposite to the face in which the connecting unit is provided and the rod portion includes, at the feeder terminal, a securing unit for securing the heating element, and the rod portion includes a hollow portion between the connecting unit and the securing unit. This provides a heating element that can prevent corrosion of a feeder terminal, possesses high durability, can be produced at low cost, and has a good temperature distribution.

### TECHNICAL FIELD

The present invention relates to a heating element that is used as a heating source which is used in wafer heating and raw material heating processes in, for example, a semiconductor device or optical device production process and at the time of production of a single crystal, the heating element that is used, for example, at the time of production of a solar cell.

### BACKGROUND ART

In the past, as a resistance heating-type heater that is used in a semiconductor process or an optical process, a resistance heating-type heater that is formed by winding or bonding, as a heat generator, a wire rod or foil of a high melting point metal such as molybdenum or tungsten around or to a support substrate made of sintered ceramic such as alumina, aluminum nitride, zirconia, or boron nitride and then placing an electrical insulating ceramic plate thereon or a resistance heating-type heater obtained by directly burying a heat generator and performing concurrent sintering has been used. Moreover, as an improvement thereof, a resistance heating-type heating element with a heat generating layer of conductive ceramic provided on an electrical insulating ceramic support substrate and a coating of electrical insulating ceramic thereon has been developed to increase the electric insulating property and corrosion resistance.

In general, as a ceramic support substrate, a sintered body obtained by adding a sintering agent to raw material powder and performing sintering is used. However, since the sintering agent is added, there is the fear of impurity contamination or a reduction in corrosion resistance at the time of heating. Furthermore, a problem arises in terms of thermal shock resistance because the ceramic support substrate is the sintered body. In particular, in the case of a large ceramic support substrate, there is the fear of, for example, a fracture in a base material which is caused by nonuniform sintering characteristics, which makes it impossible to apply the ceramic support substrate to a process that requires sharp temperature rise and decrease.

Thus, an integral-type resistance heating-type multilayer ceramic heater formed by joining, to the front surface of a support substrate which is made of pyrolytic boron nitride (hereinafter also referred to as PBN) and formed by thermo-chemical vapor deposition (hereinafter also referred to as thermo-CVD), a heat generating layer which is made of pyrolytic graphite (hereinafter also referred to as PG) and formed by thermo-CVD, the heat generating layer covered with a closely packed, laminated protective layer made of the same material as the support substrate, has been developed and widely used in various fields that require sharp temperature rise and decrease, in particular, a continuous process or the like which is single wafer processing by which semiconductor wafers and so forth are processed one by one and performs processing while changing the temperature in stages as a high-purity and chemically stable heater that is resistant to thermal shock.

Moreover, since all of the constituent members of this multilayer ceramic heater are fabricated by thermo-CVD, the constituent members have no grain boundary which is observed in sintered ceramic formed by sintering powder and are closely packed and do not occlude gas and therefore do not outgas. For this reason, the use of the multilayer ceramic heater is also expanded as a heater that does not affect the degree of vacuum in an in-vacuo process.

Under present circumstances, in such a heating element, in general, in order to energize the heat generator, a hole is formed in a portion which becomes a terminal and a conductive layer is exposed by removing part of the electrical insulating ceramic covering the heat generator, and a bolt is tightened with a washer or the like placed thereon to achieve energization.

However, since the pyrolytic graphite which is the heat generator is sensitive to oxidative consumption and has reactivity with a high-temperature gas that is used in a process, such as methane gasification by hydrogen, the pyrolytic graphite in a feeder terminal portion which is exposed for power feeding is consumed by oxygen remaining in the process or the high-temperature gas which is used in the process, which shortens the life of the feeder terminal portion.

To solve this problem, attempts to distance the feeder terminal portion from a heat generating portion have been made. For instance, a proposal to prevent overheating of the feeder terminal portion and increase the life of a feeder terminal by connecting the feeder terminal to a power-supply terminal component via a feeder component having a heater pattern which generates heat by energization and using electrical insulating ceramic such as PBN as a protective layer covering the heater pattern (Patent Document 1) has been made.

Furthermore, a method by which a protective layer is formed after a feeder terminal portion made of carbon is fabricated by assembly has been proposed (Patent Documents 2 and 3).

However, a crack easily appears by the use in the protective layer near a connecting portion assembled by combining a plurality of parts, and the crack can give rise to corrosion of a conductive layer, which shortens the life. In particular, it is revealed that, when a rod portion is connected by inserting a bolt through a base material from above, a crack in the protective layer easily appears in a boundary surface between the base material and the bolt.

In another invention, a proposal to form a heat generator and a feeder terminal portion as an integrated heat-resistant base material and thereby make it resist a crack by the use and increase the life has been made (Patent Document 4).

However, in this invention, cost for machining to form the heat generator and the feeder terminal portion as an integrated object is needed. Thus, assembling a plurality of parts by combining them is more advantageous in terms of cost.

Moreover, a drawback of providing a rod portion in such a support substrate (a plate-like portion) is that an escape of heat from the rod portion causes a local reduction in the temperature of a heat generating portion, which results in a poor temperature distribution. Furthermore, another drawback is that, since heat escapes from a terminal portion in a similar manner, a local reduction in the temperature of the heat generating portion is caused, which results in a poor temperature distribution.

### CITATION LIST

### Patent Literature

Patent Document 1: Japanese Unexamined Patent Application publication (Kokai) No. H11-354260

Patent Document 1: Japanese Unexamined Patent Application publication (Kohyo) No. H8-500932

Patent Document 1: Japanese Unexamined Patent Application publication (Kokai) No. 2013-45511

Patent Document 1: Japanese Unexamined Patent Application publication (Kokai) No. 2007-73492

### SUMMARY OF THE INVENTION

### Technical Problem

The present invention has been made in view of the problems, and an object thereof is to provide a heating element that can prevent corrosion of a feeder terminal, possesses high durability, can be produced at low cost, and has a good temperature distribution.

### Solution to Problem

To solve the problems, the present invention provides a heating element including: a heat generator including a support substrate on which a heater pattern is formed; and a rod portion that is connected to one side of the heat generator and is provided for energizing the heat generator, wherein, in a connecting portion of the rod portion in which the rod portion is connected to the heat generator, a connecting unit is provided in a face of the rod portion on which the rod portion is connected to the heat generator, a feeder terminal for feeding power to the heating element is formed on a face of the rod portion opposite to the face in which the connecting unit is provided and the rod portion includes, at the feeder terminal, a securing unit for securing the heating element, and the rod portion includes a hollow portion between the connecting unit and the securing unit.

Such a heating element can curb the heat that escapes from the rod portion by the presence of the hollow portion and therefore is a heating element that can prevent corrosion of the feeder terminal and prevent appearance of a crack in a protective layer in a boundary surface between the support substrate and a fastening bolt, possesses high durability, can be produced at low cost, and has a good temperature distribution.

At this time, it is preferable that the connecting unit is a connecting hole and the securing unit is a securing hole.

This makes it possible to connect the rod portion and the heat generator and secure the heating element with ease.

Moreover, at this time, it is preferable that the hollow portion has a cross-sectional area larger than the cross-sectional area of the connecting hole and the cross-sectional area of the securing hole.

This enhances the effect of preventing heat from escaping from the rod portion and thereby provides a heating element that can reliably prevent corrosion of the feeder terminal and prevent appearance of a crack in a protective layer in a boundary surface between the support substrate and a fastening bolt, possesses higher durability, can be produced at lower cost, and has a better temperature distribution.

Furthermore, at this time, it is preferable that the connecting hole or the securing hole or both the connecting hole and the securing hole pass through the rod portion to the hollow portion thereof and communicate with the hollow portion.

This allows the material of the heater pattern to reach even the hollow portion, for example, of the rod portion through the spaces communicating with the hollow portion by screw holes or the like at the time of the formation of the heater pattern and thereby provides better electrical conduction in the connecting portion.

In addition, at this time, it is preferable that, on the outside of the support substrate and the rod portion, a layer made of pyrolytic graphite or pyrolytic graphite containing boron is formed and a layer made of pyrolytic graphite or pyrolytic graphite containing boron is also formed on the inside of the hollow portion of the rod portion in a continuous manner via the feeder terminal.

This makes it possible to provide a heating element that has high heat resistance and suffers little thermal degradation.

Moreover, at this time, it is preferable that the proportion of the cross-sectional area of the hollow portion in the entire cross-sectional area of the rod portion is 25% or more and 95% or less.

This makes it possible to effectively curb the heat that escapes through the rod portion. In particular, if the proportion of the cross-sectional area of the hollow portion in the entire cross-sectional area of the rod portion is 25% or more, the heat that escapes through the rod portion can be reduced, which makes it possible to suppress a reduction in the temperature of the heat generator. Moreover, if the proportion of the cross-sectional area of the hollow portion in the entire cross-sectional area of the rod portion is 95% or less, it is possible to reliably prevent heat from escaping and suppress a reduction in mechanical strength caused by the small remaining thickness of the rod portion, which eliminates the fear of breakage at the time of the formation of the hollow portion.

Furthermore, at this time, it is preferable that the heating element is provided with a conducting path which is formed from the feeder terminal to the heater pattern by way of the side face of the rod portion and the side face of the heat generator.

With such a heating element, it is possible to feed power to the heater pattern by the conducting path separately formed on the side face of the rod portion even when electrical conduction becomes impossible because of damage or a spark in the connecting portion, for example, on a route through which power is fed via the rod portion which is an electric conductor and perform long-term energization. Conversely, even when electrical conduction via the conducting path formed on the side face of the rod portion becomes impossible, since power can be fed to the heater pattern through the rod portion and a fastening bolt and one of the routes can energize the heater pattern, it is possible to increase the longevity of the heating element.

In addition, at this time, it is preferable that the support substrate and the rod portion are formed of a material selected from stainless steel, Inconel, molybdenum, tungsten, tantalum, alumina, aluminum nitride, boron nitride, a complex of aluminum nitride and boron nitride, pyrolytic boron nitride, graphite coated with pyrolytic boron nitride, and graphite or a combination of these materials.

This makes it possible to provide a heating element that is of high purity, has high heat resistance, and possesses high durability.

### Advantageous Effects of Invention

The heating element of the present invention is a heating element that has a good temperature distribution as a result of an escape of heat from the rod portion being prevented, can prevent corrosion of the feeder terminal and prevent appearance of a crack in a protective layer in a boundary surface between the support substrate and a fastening bolt, possesses high durability and is capable of performing stable power feeding, has a long life, and can be produced at low cost. By fabricating a semiconductor device by using this heating element, it is possible to enhance yield and reduce initial cost and replacement cost.

### BRIEF DESCRIPTION OF DRAWINGS

FIGS. 1A and 1B are a plan view and a sectional view, respectively, which depict an example of a heating element of the present invention;

FIG. 2A is an enlarged sectional view of an area near a rod portion in the example of the heating element of the present invention, FIG. 2B is a cross-sectional plan view taken along the line A-A of FIG. 2A, and FIG. 2C is an enlarged view of a portion enclosed in a square in FIG. 2B;

FIG. 3A is an enlarged sectional view of an area near the rod portion in another example of the heating element of the present invention, FIG. 3B is a cross-sectional plan view taken along the line A-A of FIG. 3A, and FIG. 3C is an enlarged view of a portion enclosed in a square in FIG. 3B;

FIG. 4A is an enlarged sectional view of an area near the rod portion in still another example of the heating element of the present invention, FIG. 4B is a cross-sectional plan view taken along the line A-A of FIG. 4A, and FIG. 4C is an enlarged view of a portion enclosed in a square in FIG. 4B;

FIG. 5A is an enlarged sectional view of an area near the rod portion of still another example of the heating element of the present invention, FIG. 5B is a cross-sectional plan view taken along the line A-A of FIG. 5A, and FIG. 5C is an enlarged view of a portion enclosed in a square in FIG. 5B; and

FIG. 6A is an enlarged sectional view of an area near a rod portion in an example of an existing heating element, FIG. 6B is a cross-sectional plan view taken along the line A-A of FIG. 6A, and FIG. 6C is an enlarged view of a portion enclosed in a square in FIG. 6B.

### DESCRIPTION OF EMBODIMENTS

As described earlier, a heating element that can prevent corrosion of a feeder terminal, possesses high durability, can be produced at low cost, and has a good temperature distribution is needed.

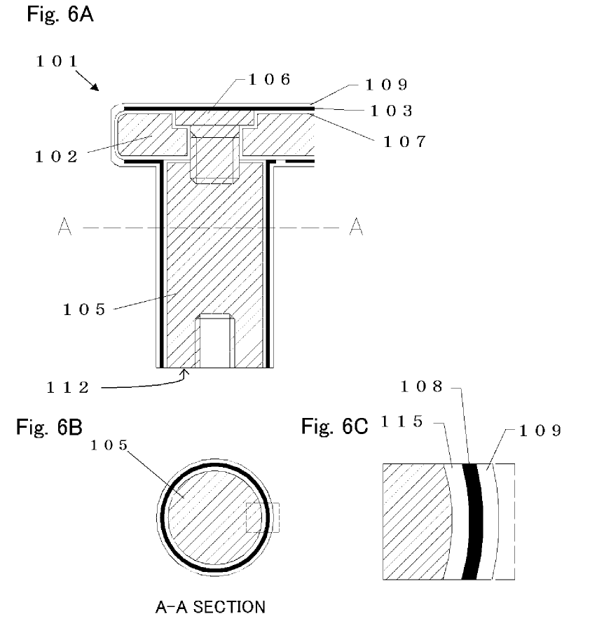

FIG. 6A is an enlarged sectional view of an area near a rod portion in an example of an existing heating element, FIG. 6B is a cross-sectional plan view taken along the line A-A of FIG. 6A, and FIG. 6C is an enlarged view of a portion enclosed in a square in FIG. 6B.

As depicted in FIG. 6A, in an existing heating element 101, a support substrate 102 is connected to a rod portion 105 by a fastening bolt 106. In this case, a drawback is that an escape of heat from the rod portion 105 causes a local reduction in the temperature of a heat generating portion in a connecting portion, which results in a poor temperature distribution. Incidentally, as depicted in FIG. 6A, on the upper surface of the support substrate 102, an insulating layer 107, a heater pattern 103, and a protective layer 109 are formed in this order. Moreover, as depicted in FIGS. 6B and 6C, the bottom face of the rod portion 105 serves as a feeder terminal 112, and, on the side face of the rod portion 105, an insulating layer 115, a conductive layer 108, and a protective layer 109 are formed in this order.

As a result of an intensive study of the problem, the inventors of the present invention have found out that, since a heating element that includes a heat generator including a support substrate on which a heater pattern is formed and a rod portion that is connected to one side of the heat generator and is provided for energizing the heat generator, the heating element in which, in a connecting portion of the rod portion in which the rod portion is connected to the heat generator, a connecting unit is provided in a face of the rod portion on which the rod portion is connected to the heat generator, a feeder terminal for feeding power to the heating element is formed on a face of the rod portion opposite to the face in which the connecting unit is provided and the rod portion includes, at the feeder terminal, a securing unit for securing the heating element, and the rod portion includes a hollow portion between the connecting unit and the securing unit, can prevent heat from escaping through the rod portion and thereby prevent a reduction in the temperature of the connecting portion of the rod portion in which the rod portion is connected to the heat generator, it is possible to improve uniformity of the temperature of the support substrate, and completed the present invention.

Hereinafter, the present invention will be described in detail, but the present invention is not limited to the following description.

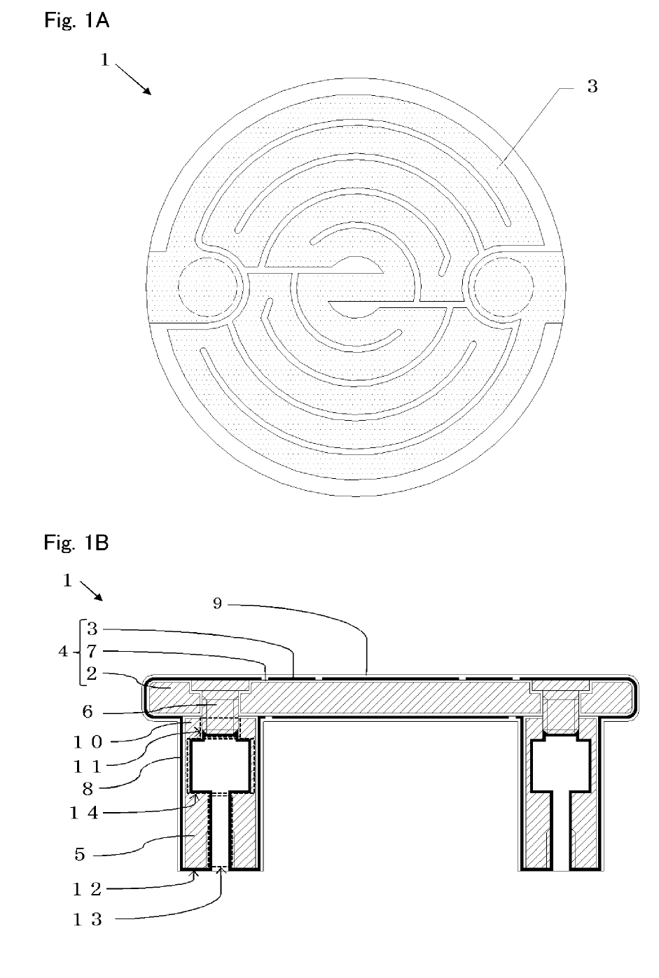

FIG. 1A is a plan view depicting an example of a heating element of the present invention, and FIG. 1B is a sectional view depicting the example of the heating element of the present invention.

As depicted in FIG. 1, a heating element 1 includes a heat generator 4 including a support substrate 2 (a plate-like portion) on which a heater pattern 3 is formed and a rod portion 5 that is connected to one side of the heat generator 4 and is provided for energizing the heat generator 4.

The support substrate 2 and the rod portion 5 only have to be connected (joined) by using a simple method by which the support substrate 2 and the rod portion 5 are screwed together by a bolt. For instance, as depicted in FIG. 1, the support substrate 2 and the rod portion 5 are connected and secured by a fastening bolt 6 having electrical conductivity (made of graphite, for example). Incidentally, in the support substrate 2, a recess into which an end of the rod portion 5 is inserted may be provided. On the other hand, the rod portion 5 includes a hollow portion 14 and is provided with a connecting unit 11 at the upper end thereof, which is threaded so that the fastening bolt 6 can be threaded thereinto. It is to be noted that the support substrate 2 and the rod portion 5 may be connected not only by a screw, but also by a pin or press-fit, for example.

Typically, the support substrate 2 has the shape of, for example, a circular plate, a rectangular plate, or a ring, but the support substrate 2 may have any shape as long as the support substrate 2 has a plate-like shape. Moreover, as the support substrate 2, a support substrate made of graphite, for example, can be used.

The support substrate 2 includes a through hole portion into which the fastening bolt 6 is inserted in advance, and the entire surface of the support substrate 2 is coated with an insulating layer 7.

The entire surface of the support substrate 2 and the rod portion 5 joined by the fastening bolt 6 is coated with a conductive layer 8 made of pyrolytic graphite by CVD, for example. Then, the heater pattern 3 is formed in such a way that the conductive layer on the upper surface of the support substrate 2 becomes a heat generating portion. The heater pattern 3 is formed by using machining or screen printing.

The heater pattern 3 is formed of a high melting point metal such as tungsten, tantalum, or molybdenum or a publicly known material suitable for a heater, such as pyrolytic graphite, silicon carbide, or molybdenum silicide. The heater pattern 3 can be formed by the following method: a pattern is formed by chemical vapor deposition (CVD), ion plating, or a printing process and then heat treatment is performed if necessary. In particular, CVD is preferable because a source gas reaches even the hollow portion of the rod portion in a gaseous phase when, as will be described later, the connecting unit and a securing unit of the rod portion communicate with the hollow portion.

As depicted in FIG. 1B, the uppermost surface of the support substrate 2 is covered with a protective layer 9 of pyrolytic boron nitride or the like by CVD, for example, which prevents the heater pattern 3 from being exposed to corrosive gas and consumed thereby and further extends the life thereof.

By forming the protective layer covering the heater pattern 3 by using the same material as the support substrate, it is possible to obtain the heating element in which a difference in thermal expansion between the protective layer and the support substrate is small, which makes the heating element resistant to deformation. The protective layer can be formed by a method by which a protective layer and a base material are sintered at the same time or a method by which a protective layer is formed by sputtering, chemical vapor deposition (CVD), ion plating, or a printing process and then heat treatment is performed if necessary.

Examples of the material of the protective layer include yttria, magnesium oxide, alumina, aluminum nitride, and pyrolytic boron nitride, and the protective layer can be stably used even in an atmosphere containing fluorine-based gas, ammonia gas, hydrogen gas, hydrogen chloride gas, or oxygen.

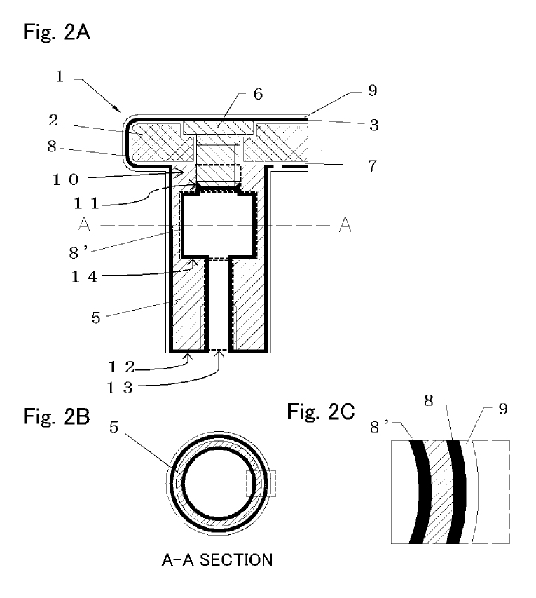

FIG. 2A is an enlarged sectional view depicting an area near the rod portion in the example of the heating element of the present invention, FIG. 2B is a cross-sectional plan view taken along the line A-A of FIG. 2A, and FIG. 2C is an enlarged view of a portion enclosed in a square in FIG. 2B.

Hereinafter, with reference to FIG. 2, the rod portion in the heating element of the present invention will be described in more detail.

In a connecting portion 10 of the rod portion 5 in which the rod portion 5 is connected to the heat generator 4, the connecting unit 11 (a connecting hole (a threaded hole)) into which the fastening bolt 6 is threaded is provided in a face of the rod portion 5 on which the rod portion 5 is connected to the heat generator 4, a feeder terminal 12 for feeding power to the heating element 1 is formed on a face of the rod portion 5 opposite to the face in which the connecting unit 11 is provided, and the rod portion 5 includes, at the feeder terminal 12, a securing unit 13 (a securing hole (a threaded hole)) which connects to feeder wiring and is provided to secure the heating element 1. Incidentally, the feeder terminal 12 may have the shape of an external thread.

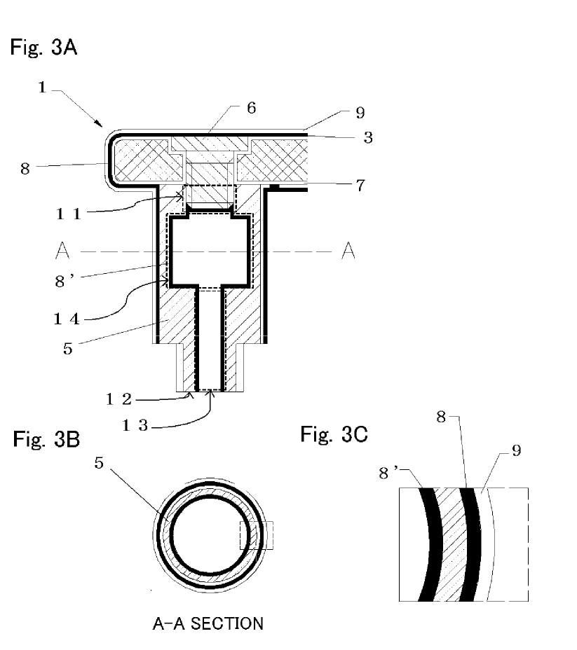

Examples of the shape of the rod portion 5 include a circular cylinder and a rectangular cylinder, and part of the rod portion 5 may be chamfered. Moreover, the rod portion 5 may taper or the thickness thereof may change in a step-like manner in the direction of the length thereof. For example, as depicted in FIG. 3, the rod portion 5 may have a shape in which the side where the feeder terminal is located is convex. Furthermore, as the rod portion 5, a rod portion made of graphite, for example, can be used.

Moreover, in the present invention, the rod portion 5 includes the hollow portion 14 between the connecting unit 11 and the securing unit 13. As a result of the rod portion including such a hollow portion, it is possible to prevent heat from escaping through the rod portion, which makes it possible to prevent a reduction in the temperature of the connecting portion 10 and improve uniformity of the temperature of the support substrate.

Furthermore, it is possible to prevent appearance of a crack in a protective layer in a boundary surface between a base material (a support substrate) and a fastening bolt which would occur when a rod portion is connected by inserting the fastening bolt into the support substrate. It is believed that, in the past, a reduction in the temperature of the rod portion in the connecting portion caused a difference in thermal expansion between the rod portion in the connecting portion and the support substrate and the tensile stress produced thereby made a crack appear easily. It is believed that providing the rod portion with the hollow portion described above improves uniformity of the temperature, which reduces a difference in thermal expansion between the rod portion in the connecting portion and the support substrate and also reduces tensile stress which is applied to the protective layer, contributing to suppression of a crack.

As described above, the heating element of the present invention can prevent heat from escaping from the rod portion by the presence of the hollow portion and obtain a good temperature distribution of the support substrate. If a hollow portion (space) is not provided in a rod portion, a reduction in the temperature is caused by escaping heat and thermal stress produced by a difference in thermal expansion due to the temperature difference makes a crack appear in a heater pattern or a protective layer. By contrast, with the heating element of the present invention, this thermal stress is not produced, whereby it is possible to prevent the appearance of a crack in the heater pattern and the protective layer.

It is preferable that the hollow portion 14 has a cross-sectional area larger than the cross-sectional area of the connecting unit 11 (the connecting hole) and the cross-sectional area of the securing unit 13 (the securing hole). Such a relationship between the cross-sectional area of the hollow portion 14 and the cross-sectional areas of the connecting unit 11 and the securing unit 13 makes it possible to effectively cut off a movement of heat between the side where the connecting unit 11 is located and the side where the securing unit 13 is located and improves the heat insulating effect and the heat retaining effect produced by the hollow portion 14 and uniformity of the temperature of the heat generator.

Moreover, it is preferable that the proportion of the hollow portion in the entire cross-sectional area of the rod portion (the cross-sectional area of the rod portion in a cross-section in a direction perpendicular to the energization direction of the rod portion) is 25% or more and 95% or less. The above proportion of the hollow portion in the entire cross-sectional area of the rod portion makes it possible to reduce the heat that escapes through the rod portion. If the proportion of the hollow portion in the entire cross-sectional area of the rod portion is 25% or more, it is possible to reliably reduce the heat that escapes through the rod portion as compared to when the hollow portion is not provided and therefore prevent a temperature reduction. Moreover, if the proportion of the hollow portion in the entire cross-sectional area of the rod portion is 95% or less, it is possible to prevent heat from escaping and prevent a reduction in mechanical strength caused by the small remaining thickness of the rod portion, which eliminates the fear of breakage at the time of the formation of the hollow portion and also eliminates the fear of appearance of a crack in the rod portion when a bolt is fastened tightly to secure the rod portion to the feeder wiring. More preferably, the proportion of the hollow portion in the entire cross-sectional area of the rod portion is 50% or more and 90% or less, and, still more preferably, the proportion is 75% or more and 90% or less.

Moreover, it is preferable that the connecting unit (the connecting hole) or the securing unit 13 (the securing hole) or both of the connecting unit 11 (the connecting hole) and the securing unit 13 (the securing hole) pass through the rod portion 5 to the hollow portion 14 thereof and communicate with the hollow portion 14. In particular, as depicted in FIG. 2A, it is preferable that the threaded holes (the connecting unit 11 and the securing unit 13) at both ends are provided in the direction of the length of the rod portion 5 in such a way as to pass through the rod portion 5 to the hollow portion 14 and communicate with the hollow portion 14.

For example, as depicted in FIG. 2A, as a result of the connecting unit 11 and the securing unit 13 passing through the rod portion to the hollow portion 14 and communicating with the hollow portion 14, the material of the heater pattern reaches the fastening bolt 6, a portion (clearance) in the connecting unit 11 which is not in contact with the fastening bolt 6, and even the inner surface of the hollow portion 14 through the spaces communicating with the hollow portion 14 by screw holes or the like at the time of the formation of the conductive layer and the heater pattern as described above, which provides better electrical conduction in the connecting portion.

Incidentally, a space may be made to communicate with the hollow portion 14, not from the tip (in particular, the securing unit 13) of the rod portion 5 at which the feeder terminal 12 is formed, from a radial direction somewhere along the rod portion, for example. However, in order to eliminate the fear of a decrease in the mechanical strength of the rod portion or internal corrosion as a result of the entry of the corrosive gas through the space, it is preferable to make the space communicate with the hollow portion 14 from the securing unit 13 of the rod portion 5. Doing so makes it possible to offer the advantage that threaded engagement with a feeder thread portion (the securing unit 13) makes the entry of the corrosive gas less likely to occur with the mechanical strength of the rod portion being maintained.

As depicted in FIG. 2A, when the connecting unit 11 and the securing unit 13 are made to communicate with the hollow portion 14, the source gas reaches the inner surface of the hollow portion 14 through the securing unit 13 at the tip of the rod portion 5 and even the fastening bolt 6 by which the support substrate 2 is fastened when the entire surface of the support substrate 2 and the rod portion 5 joined by the fastening bolt 6 is coated with the conductive layer 8 made of pyrolytic graphite by CVD, for example, and a coating of a conductive layer 8′ is formed. By so doing, the rod portion and the fastening bolt 6 are joined more securely and joint strength is increased. If the screw hole is coated with the pyrolytic graphite and becomes narrowed, the screw thread can be returned to the original shape by performing thread cutting again.

Furthermore, it is preferable that, on the outside of the support substrate 2 and the rod portion 5, a layer made of pyrolytic graphite or pyrolytic graphite containing boron is formed and a layer made of pyrolytic graphite or pyrolytic graphite containing boron is also formed on the inside of the hollow portion 14 of the rod portion 5 in a continuous manner via the feeder terminal 12. This makes it possible to make the heating element highly resistant to heat and suffer little thermal degradation.

By using CVD (chemical vapor deposition) in forming the layer made of pyrolytic graphite or pyrolytic graphite containing boron, it is possible to offer the advantage that the gas of the raw material easily reaches even the clearance described above and the inner surface of the hollow portion 14 through the screw holes or the like communicating with the hollow portion 14, which ensures better electrical conduction of the connecting portion.

In the heating element of the present invention, the heater pattern 3 generates heat by being energized through the rod portion 5 and the fastening bolt 6, which are electric conductors. In the present invention, as depicted in FIG. 2A, by also coating the under surface and the side face of the support substrate 2 with the conductive layer 8, it is possible to form a conducting path such that power can be fed to the heater pattern 3 via this conductive layer 8. By doing so, even when trouble occurs in energization which is performed via the fastening bolt 6 from the rod portion, the heater pattern can be energized via the conducting path formed on the side face of the support substrate, which makes it possible to achieve a longer life.

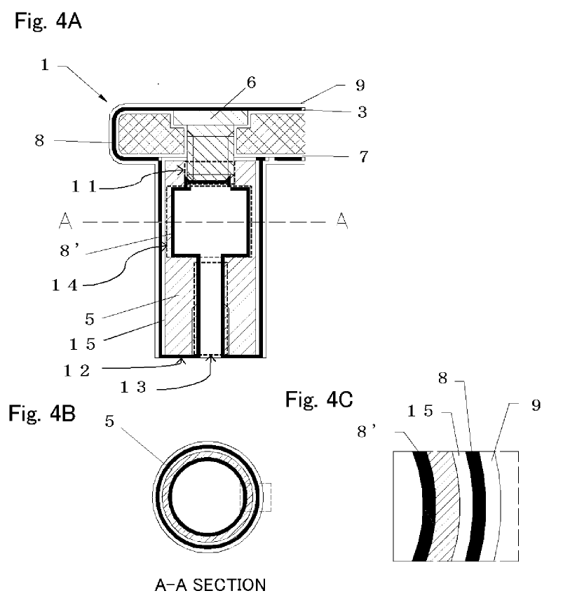

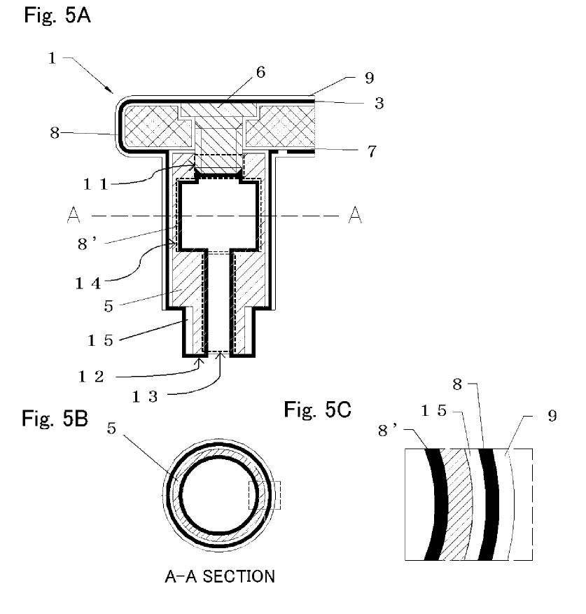

Furthermore, it is preferable that the heating element of the present invention has formed therein a conducting path connecting to the heater pattern 3 from the feeder terminal 12 via the side face of the rod portion 5 and the side face of the heat generator 4. When such a conducting path is provided separately on the side face (outer periphery) of the rod portion 5, the side face of the rod portion 5 may be coated with an insulating layer 15 in advance as depicted in FIG. 4. Moreover, when the rod portion 5 has a shape in which the side where the feeder terminal is located is convex, by coating the side face of the rod portion 5 with the insulating layer 15 in advance as depicted in FIG. 5, it is possible to provide a conducting path separately on the side face of the rod portion 5.

As described above, by separately forming a conducting path on the side face of the rod portion so as to connect to the heater pattern, even when electrical conduction becomes impossible because of damage or a spark in the connecting portion, for example, on a route through which power is fed via the rod portion which is an electric conductor, it is possible to feed power to the heater pattern through the conducting path separately formed on the side face of the rod portion and thereby perform long-term energization. Conversely, even when electrical conduction via the conducting path formed on the side face of the rod portion becomes impossible, power can be fed to the heater pattern through the rod portion and the fastening bolt 6 and one of the routes can energize the heater pattern, it is possible to increase the longevity of the heating element.

Incidentally, the material of the support substrate 2 and the rod portion 5 is not limited to graphite coated with the protective layer. It is preferable that the support substrate 2 and the rod portion 5 are formed of a material selected from a refractory metal such as stainless steel, Inconel, molybdenum, tungsten, or tantalum, alumina (Al₂O₃), aluminum nitride (AlN), boron nitride (BN), a complex of aluminum nitride (AlN) and boron nitride (BN), pyrolytic boron nitride (PBN), graphite coated with pyrolytic boron nitride, and graphite or a combination of these materials. By using these materials, it is possible to provide the heating element that is robust even in high temperatures, is of high purity, has high heat resistance, and possesses high durability, which makes the heating element suitable for a heating support substrate.

Moreover, the description deals with an example in which the connecting unit 11 is a connecting hole and the securing unit 13 is a securing hole, but the present invention is not limited to this example. That is, in the heating element of the present invention, the connecting unit 11 and the securing unit 13 are not limited to holes and may be external threads.

As described above, although the heating element of the present invention is a heating element in which a support substrate and a rod portion are connected, since a good temperature distribution is achieved and the appearance of a crack is prevented, the heating element of the present invention has the advantage of being produced at lower cost than a heating element in which a support substrate and a rod portion are integrally formed.

### EXAMPLE

Hereinafter, the present invention will be described more specifically with Examples and Comparative Example, but the present invention is not limited in any way by these examples.

### Examples 1 to 9

First, a support substrate (a plat-like body) made of graphite having a diameter of 130 mm and a thickness of 10 mm was prepared, and a through hole into which a bolt is inserted was provided in advance in a position which becomes a heater terminal. This support substrate was coated with an insulating layer of pyrolytic boron nitride with a thickness of about 100 μm.

In addition to this, a rod portion made of graphite, which forms a feeder terminal, having a diameter of 20 mm and a length of 40 mm was prepared. On one face of the rod portion, a screw hole (a connecting unit) was provided for connection to the support substrate, and, in a portion on the other face corresponding to the feeder terminal, a screw hole (a securing unit) for connecting the feeder terminal to feeder wiring was provided.

Furthermore, a hollow portion was provided in advance in a portion located midway between the screw holes. This hollow portion was provided with holes so as to communicate with the screw holes.

Here, as the rod portions used in Examples 1 to 9, various rod portions formed by changing the size of the hollow portion (the proportion of the cross-sectional area thereof in the entire cross-sectional area of the rod portion, that is, the cross-sectional area of the rod portion in a direction perpendicular to the energization direction of the rod portion) from 20 to 96% were prepared.

Next, the support substrate with the insulating layer and the rod portion were connected and secured by a bolt made of graphite, and a 50-μm-thick pyrolytic graphite layer was formed by CVD over the entire surface of the support substrate and the rod portion in a fastened state. This pyrolytic graphite layer was also formed in the hollow portion and a screw portion, the hollow portion provided in the rod portion and communicating with the securing unit, by letting the pyrolytic graphite layer make an entry therein. Then, machining was performed on a support substrate portion to form a heater pattern.

Finally, a 100-μm-thick pyrolytic boron nitride protective layer was formed by CVD over the entire surface other than the feeder terminal, whereby a heating element whose area near the rod portion was in a state depicted in FIG. 2 was fabricated.

The heating element thus obtained was set in a chamber, wiring was carried out at the tip of the feeder terminal, and the heating element was fixed by a bolt. In so doing, when the bolt was fastened by a fastening torque wrench set at 10 N·m, it was checked whether or not the rod portion was damaged. The results are shown in Table 1.

Furthermore, after being set, the heating element was heated by energizing the terminal portion, whereby the temperature of the heating element was raised to 1400° C., and then ammonia was supplied to the inside of the chamber at a rate of 1 L/min and the pressure inside the chamber was adjusted to 5000 Pa. The heating element was kept in this state for 100 hours, and the temperature at the center of the support substrate and the temperature of a part (a connecting portion) in which the rod portion was connected to the support substrate were measured and a temperature difference therebetween was assumed to be ΔT. Moreover, the presence or absence of a break by corrosion was also checked. These results are shown in Table 1.

Incidentally, the temperature difference was evaluated by the following standards, and the evaluation results are shown in Table 1 below.

Excellent: ΔT of 15° C. or less

Good: ΔT of more than 15° C. and 25° C. or less

Average: ΔT of more than 25° C. and 50° C. or less

Poor: ΔT of more than 50° C.

Moreover, the comprehensive evaluation was made by the following standards, and the evaluation results are shown in Table 1 below.

Excellent: ΔT of 15° C. or less

Good: ΔT of more than 15° C. and 50° C. or less or ΔT of 15° C. or less but with a few cracks

Poor: ΔT of more than 50° C.

### Comparative Example 1

A heating element was fabricated in the same manner as Examples 1 to 9 except that a rod portion without a hollow portion (the proportion of the cross-sectional area of the hollow portion: 0%) was used and evaluated.

TABLE 1

| | Outside diameter | Inside diameter | Proportion | | | | |
|---|---|---|---|---|---|---|---|
| | of the rod | of the hollow | of the | | | | |
| | portion | portion | hollow | Temperature | Mechanical | Break by | Comprehensive |
| | (mm) | (mm) | portion | difference | strength | corrosion | evaluation |
| Comparative | 20 | 0 | 0% | 60° C.: Poor | Good | Partly | Poor |
| Example 1 | | | | | | | |
| Example 1 | 20 | 9 | 20% | 50° C.: Average | Good | No break | Good |
| Example 2 | 20 | 10 | 25% | 45° C.: Average | Good | No break | Good |
| Example 3 | 20 | 12 | 36% | 25° C.: Good | Good | No break | Good |
| Example 4 | 20 | 14 | 49% | 20° C.: Good | Good | No break | Good |
| Example 5 | 20 | 16 | 64% | 15° C.: Excellent | Good | No break | Excellent |
| Example 6 | 20 | 18 | 81% | 13° C.: Excellent | Good | No break | Excellent |
| Example 7 | 20 | 19 | 90% | 10° C.: Excellent | Good | No break | Excellent |
| Example 8 | 20 | 19.3 | 93% | 8° C.: Excellent | Good | No break | Excellent |
| Example 9 | 20 | 19.6 | 96% | 8° C.: Excellent | A few | No break | Good |
| | | | | | cracks | | |

As shown in Table 1, it was confirmed that, if no hollow portion was provided as in Comparative Example 1, the temperature difference ΔT exceeded 50° C., resulting in a poor temperature distribution, and there was corrosion in some areas; by contrast, if the proportion of the cross-sectional area of the hollow portion was 20% or more as in Examples 1 to 9, the temperature difference ΔT became 50° C. or less and a good temperature distribution was achieved. Moreover, as shown in Table 1, it was confirmed that, in Example 9 in which the proportion of the cross-sectional area of the hollow portion exceeded 95%, the remaining thickness of the rod portion became small and a few cracks appeared in the rod portion when the bolt was fastened with a torque wrench set at 10 N·m at the tip of the feeder terminal; however, in the heating elements of Examples 1 to 8, no crack appeared and these heating elements had sufficient strength. In addition, the heating elements of Examples 1 to 9 did not suffer a break caused by corrosion.

### Example 10

As in Examples 1 to 9, a support substrate made of graphite and coated with an insulating layer of pyrolytic boron nitride with a thickness of about 100 μm and a rod portion made of graphite were prepared. Incidentally, the proportion of the cross-sectional area of the hollow portion provided in the rod portion in the cross-sectional area of the rod portion in a direction perpendicular to the energization direction of the rod portion was set at 81%.

The support substrate and the rod portion were fastened by a bolt made of graphite, a 50-μm-thick pyrolytic graphite layer was provided in this state, and machining was performed on the upper surface of the support substrate to form a heater pattern in such a way that power could be fed via the fastening bolt through the rod portion, and, at the same time, connection to the same heater pattern from the rod portion via the pyrolytic graphite layer on the under surface and the side face of the support substrate was made possible.

Finally, a 100-μm-thick pyrolytic boron nitride protective layer was formed on this heater pattern and the entire surface except for the feeder terminal was coated with this protective layer, whereby a heating element whose area near the rod portion was in a state depicted in FIG. 4 was fabricated.

The heating element thus obtained was set in a chamber, and, after the temperature thereof was raised to 1400° C., ammonia was supplied to the inside of the chamber at a rate of 1 L/min and the pressure inside the chamber was adjusted to 5000 Pa. Energization was performed in this state from the terminal portion of the heating element, whereby the temperature was raised to 1400° C. in five minutes, and energization was stopped two minutes after that, and the heater was cooled to 100° C. This cycle was repeated, and the state of the terminal portion was observed.

As a result, a crack appeared at the boundary between the bolt connecting the rod portion and the support substrate and the support substrate in the fifty-second temperature rise and decrease cyclic test and part of a path through which energization of a main body of the rod portion was performed was damaged. However, a path connecting to the heater pattern via the pyrolytic graphite layer on the side face of the support substrate could perform energization without problems.

Then, temperature rise and decrease could be repeated 500 times by performing energization by using this path. The path connecting to the heater pattern via the pyrolytic graphite layer on the side face of the support substrate remained in a state in which the path could perform energization without problems and operated properly.

### Example 11

As in Examples 1 to 9, a support substrate made of graphite and coated with an insulating layer of pyrolytic boron nitride with a thickness of about 100 μm and a rod portion made of graphite were prepared. As in the case of Example 6, the proportion of the cross-sectional area of the hollow portion provided in the rod portion in the cross-sectional area of the rod portion in a direction perpendicular to the energization direction of the rod portion was set at 81%.

The support substrate and the rod portion were fastened by a bolt made of graphite, a 50-μm-thick pyrolytic graphite layer was provided in this state, and machining was performed on the upper surface of the support substrate to form a heater pattern in such a way that power could be fed via the fastening bolt through the rod portion. However, a feeder path passing through the pyrolytic graphite layer on the side face of the support substrate was not provided.

Finally, a 100-μm-thick pyrolytic boron nitride protective layer was formed on this heater pattern and the entire surface except for the feeder terminal was coated with this protective layer, whereby a heating element was fabricated.

When a temperature rise and decrease cyclic test similar to that conducted in Example 10 was conducted on the heating element thus obtained, a crack appeared at the boundary between the bolt connecting the rod portion and the support substrate and the support substrate in the forty-fourth test and a path through which energization of a main body of the rod portion was performed was damaged by a spark. Due to the heat generation in this portion, the life of the heating element of Example 11 was shorter than that of the heating element of Example 10.

It is to be understood that the present invention is not limited in any way by the embodiment thereof described above. The above embodiment is merely an example, and anything that has substantially the same structure as the technical idea recited in the claims of the present invention and that offers similar workings and benefits falls within the technical scope of the present invention.

1. A heating element comprising:
a heat generator including a support substrate on which a heater pattern is formed; and
a rod portion that is connected to one side of the heat generator and is provided for energizing the heat generator,
wherein
in a connecting portion of the rod portion in which the rod portion is connected to the heat generator, a connecting unit is provided in a face of the rod portion on which the rod portion is connected to the heat generator,
a feeder terminal for feeding power to the heating element is formed on a face of the rod portion opposite to the face in which the connecting unit is provided and the rod portion includes, at the feeder terminal, a securing unit for securing the heating element, and
the rod portion includes a hollow portion between the connecting unit and the securing unit.

2. The heating element according to claim 1, wherein
the connecting unit is a connecting hole and the securing unit is a securing hole.

3. The heating element according to claim 2, wherein
the hollow portion has a cross-sectional area larger than a cross-sectional area of the connecting hole and a cross-sectional area of the securing hole.

4. The heating element according to claim 2, wherein
the connecting hole or the securing hole or both the connecting hole and the securing hole pass through the rod portion to the hollow portion thereof and communicate with the hollow portion.

5. The heating element according to claim 3, wherein
the connecting hole or the securing hole or both the connecting hole and the securing hole pass through the rod portion to the hollow portion thereof and communicate with the hollow portion.

6. The heating element according to claim 4, wherein
on an outside of the support substrate and the rod portion, a layer made of pyrolytic graphite or pyrolytic graphite containing boron is formed and a layer made of pyrolytic graphite or pyrolytic graphite containing boron is also formed on an inside of the hollow portion of the rod portion in a continuous manner via the feeder terminal.

7. The heating element according to claim 5, wherein
on an outside of the support substrate and the rod portion, a layer made of pyrolytic graphite or pyrolytic graphite containing boron is formed and a layer made of pyrolytic graphite or pyrolytic graphite containing boron is also formed on an inside of the hollow portion of the rod portion in a continuous manner via the feeder terminal.

8. The heating element according to claim 1, wherein
a proportion of a cross-sectional area of the hollow portion in an entire cross-sectional area of the rod portion is 25% or more and 95% or less.

9. The heating element according to claim 2, wherein
a proportion of a cross-sectional area of the hollow portion in an entire cross-sectional area of the rod portion is 25% or more and 95% or less.

10. The heating element according to claim 3, wherein
a proportion of a cross-sectional area of the hollow portion in an entire cross-sectional area of the rod portion is 25% or more and 95% or less.

11. The heating element according to claim 4, wherein
a proportion of a cross-sectional area of the hollow portion in an entire cross-sectional area of the rod portion is 25% or more and 95% or less.

12. The heating element according to claim 5, wherein
a proportion of a cross-sectional area of the hollow portion in an entire cross-sectional area of the rod portion is 25% or more and 95% or less.

13. The heating element according to claim 6, wherein
a proportion of a cross-sectional area of the hollow portion in an entire cross-sectional area of the rod portion is 25% or more and 95% or less.

14. The heating element according to claim 7, wherein
a proportion of a cross-sectional area of the hollow portion in an entire cross-sectional area of the rod portion is 25% or more and 95% or less.

15. The heating element according to claim 1, wherein
the heating element is provided with a conducting path which is formed from the feeder terminal to the heater pattern by way of a side face of the rod portion and a side face of the heat generator.

16. The heating element according to claim 1, wherein
the support substrate and the rod portion are formed of a material selected from stainless steel, Inconel, molybdenum, tungsten, tantalum, alumina, aluminum nitride, boron nitride, a complex of aluminum nitride and boron nitride, pyrolytic boron nitride, graphite coated with pyrolytic boron nitride, and graphite or a combination of these materials.
